(19) United States
(12) Patent Application Publication
(10) Pub. No.: US 2025/0232993 A1
(43) Pub. Date: Jul. 17, 2025

(54) Substrate Processing Apparatus, Method of Manufacturing Semiconductor Device and Non-transitory Computer-readable Recording Medium

(71) Applicant: Kokusai Electric Corporation, Tokyo (JP)

(72) Inventors: Shin TSUJIMURA, Toyama (JP); Keiichi TSUCHINAKA, Toyama (JP); Tetsuya KOSUGI, Toyama (JP); Tsukasa YASHIMA, Toyama (JP)

(21) Appl. No.: 18/999,760

(22) Filed: Dec. 23, 2024

(30) Foreign Application Priority Data
Jan. 16, 2024 (JP) 2024-004812

(51) Int. Cl. H01L 21/67; H01L 21/66; H01L 21/673

(52) U.S. Cl. CPC H01L 21/67253; H01L 21/67248; H01L 21/67376; H01L 22/34

(57) ABSTRACT

It is possible to estimate an energy amount suitable for processing a substrate before the substrate is performed. There is provided a technique that includes: a processing structure configured to process a substrate based on at least one setting item in which process conditions for the substrate are defined; a manipulator configured to perform a setting operation for the process conditions of the at least one setting item; and a controller configured to be capable of controlling a calculation of an energy amount consumed under the process conditions which are set by the manipulator.

### CROSS REFERENCE TO RELATED APPLICATIONS

This non-provisional U.S. patent application is based on and claims priority under 35 U.S.C. § 119(a)-(d) of Japanese Patent Application No. 2024-004812 filed on Jan. 16, 2024, in the Japanese Patent Office, the entire contents of which are hereby incorporated by reference.

### TECHNICAL FIELD

The present disclosure relates to a substrate processing apparatus, a method of manufacturing a semiconductor device and a non-transitory computer-readable recording medium.

### BACKGROUND

According to some related arts, in a substrate processing apparatus, an amount of energy (also referred to as an “energy amount”) for processing a substrate may be calculated using measured values (which are obtained from various sensors during a substrate processing)

When the energy amount is calculated using the measured values obtained from the various sensors, the energy amount may not be estimated before a subsequent substrate is processed.

### SUMMARY

According to the present disclosure, there is provided a technique capable of estimating an energy amount suitable for processing a substrate before the substrate is performed.

According to an embodiment of the present disclosure, there is provided a technique that includes a processing structure configured to process a substrate based on at least one setting item in which process conditions for the substrate are defined; a manipulator configured to perform a setting operation for the process conditions of the at least one setting item; and a controller configured to be capable of controlling a calculation of an energy amount consumed under the process conditions which are set by the manipulator.

### BRIEF DESCRIPTION OF THE DRAWINGS

FIG. 1 is a diagram schematically illustrating a perspective view of an example of a configuration of a substrate processing apparatus according to one or more embodiments of the present disclosure.

FIG. 2 is a diagram schematically illustrating a cross-section of the substrate processing apparatus according to the embodiments of the present disclosure, when viewed from side.

FIG. 3 is a diagram schematically illustrating a vertical cross-section of a process furnace of the substrate processing apparatus according to the embodiments of the present disclosure.

FIG. 4 is a block diagram schematically illustrating an example of a functional configuration of a control apparatus and related components of the substrate processing apparatus according to the embodiments of the present disclosure.

FIG. 5 is a diagram schematically illustrating an example of a configuration of a recipe editing screen according to the embodiments of the present disclosure.

FIG. 6 is a diagram schematically illustrating an example of a configuration of a parameter setting screen according to the embodiments of the present disclosure.

FIG. 7 is a diagram schematically illustrating an example of a configuration of an energy consumption amount display screen according to the embodiments of the present disclosure.

FIG. 8 is a flow chart schematically illustrating an example of a sequence of an energy consumption amount calculation process according to the embodiments of the present disclosure.

### DETAILED DESCRIPTION

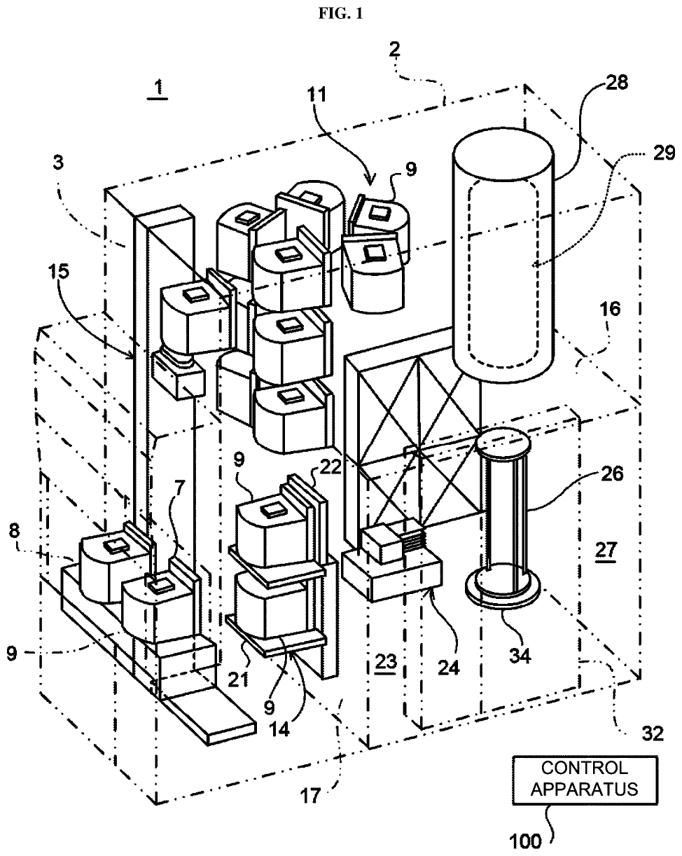

Hereinafter, one or more embodiments (also simply referred to as “embodiments”) according to the technique of the present disclosure will be described with reference to FIGS. 1 to 3. The drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match. In addition, the technique of the present disclosure is not limited to the embodiments described below. That is. the technique of the present disclosure may be appropriately modified in various ways without departing from the scope thereof.

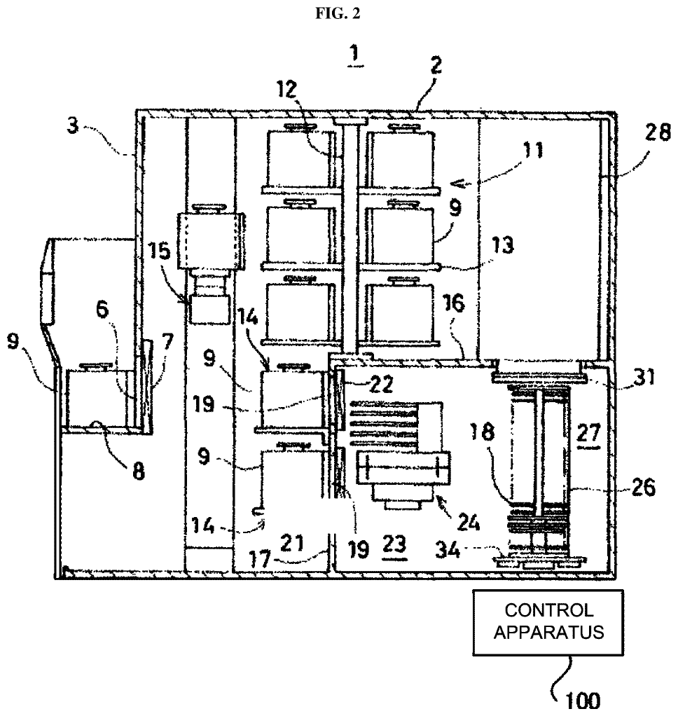

First, with reference to FIGS. 1 and 2, an outline of a substrate processing apparatus 1 according to the present embodiments will be described.

FIG. 1 is a diagram schematically illustrating a perspective view of an example of a configuration of the substrate processing apparatus 1 according to the present embodiments, and FIG. 2 is a diagram schematically illustrating a cross-section of the substrate processing apparatus 1 according to the present embodiments when viewed from side. In FIGS. 1 and 2, a vertical type substrate processing apparatus is shown as an example of the substrate processing apparatus 1, and a semiconductor wafer made of a material such as silicon is shown as an example of a substrate (that is, a wafer 18 described later) to be processed in the substrate processing apparatus 1. In the present specification, the term “wafer” may refer to “a wafer itself”, or may refer to “a wafer and a stacked structure (aggregated structure) of a predetermined layer (or layers) or a film (or films) formed on a surface of the wafer”. In the present specification, the term “a surface of a wafer” may refer to “a surface of a wafer itself”, or may refer to “a surface of a predetermined layer (or a predetermined film) formed on a wafer”. Thus, in the present specification, “forming a predetermined layer (or a film) on a wafer” may refer to “forming a predetermined layer (or a film) directly on a surface of a wafer itself”, or may refer to “forming a predetermined layer (or a film) on a surface of another layer (or another film) formed on a wafer”. In the present specification, the terms “substrate” and “wafer” may be used as substantially the same meaning.

As shown in FIGS. 1 and 2, the substrate processing apparatus 1 includes a housing 2. A pod loading/unloading port 6 is provided at a front wall 3 of the housing 2 so as to communicate between an inside and an outside of the housing 2. The pod loading/unloading port 6 may be opened or closed by a front shutter (which is a pod loading/unloading port opening/closing structure) 7. A loading port (which is a loading port shelf, that is, a transfer table for a substrate transfer container) 8 is provided in front of the pod loading/unloading port 6.

For example, a pod 9 is configured as a sealed type substrate transfer container. The pod 9 may be transferred (loaded) into and placed on the loading port 8 by an in-process transfer apparatus (not shown) and may be transferred (unloaded) out of the loading port 8 by the in-process transfer apparatus.

A rotatable pod shelf (which is a storage shelf for the substrate transfer container) 11 is provided in the housing 2 to be located over a substantially center portion of the housing 2 in a front-rear direction. The rotatable pod shelf 11 is configured such that a plurality of pods including the pod 9 can be stored (or placed) on the rotatable pod shelf 11. Hereinafter, the plurality of pods including the pod 9 may also be simply referred to as “pods 9”. The rotatable pod shelf 11 includes a plurality of shelf plates (which are placement shelves for the substrate transfer container) 13. Each of the plurality of shelf plates 13 is configured to accommodate at least one of the pods 9.

A pod opener (which is a structure capable of opening and closing a lid of the substrate transfer container) 14 is provided below the rotatable pod shelf 11. The pod opener 14 is provided with a configuration on which the pod 9 is placed and capable of opening and closing a lid of the pod 9.

A pod transfer structure (which is a container transfer structure) 15 is provided among the loading port 8, the rotatable pod shelf 11 and the pod opener 14. The pod transfer structure 15 is configured such that the pod 9 can be transferred among the loading port 8, the rotatable pod shelf 11 and the pod opener 14.

A sub-housing 16 is provided below the substantially center portion of the housing 2 in the front-rear direction to extend toward a rear end of the substrate processing apparatus 1. A pair of wafer loading/unloading ports (substrate loading/unloading ports) 19 through which the wafer 18 serving as the substrate is loaded into or unloaded out of the sub-housing 16 is provided at a front wall 17 of the sub-housing 16.

The pod opener 14 includes: a placement table 21 where the pod 9 is placed thereon; and an attaching/detaching structure 22 capable of attaching and detaching the lid of the pod 9. The pod opener 14 is configured such that a wafer entrance of the pod 9 is opened or closed by detaching or attaching the lid of the pod 9 placed on the placement table 21 by the attaching/detaching structure 22.

The sub-housing 16 defines a transfer chamber 23 fluidically isolated from a space (hereinafter, also referred to as a “pod transfer space”) in which the pod transfer structure 15 or the rotatable pod shelf 11 is provided. A wafer transfer structure (which is a substrate transfer structure) 24 is provided at a front region of the transfer chamber 23. A predetermined number of wafers (for example, as shown in FIG. 2, five wafers) placed on the wafer transfer structure 24 can be moved directly in a horizontal direction, can be rotated in the horizontal direction and can be elevated or lowered in a vertical direction. The wafer transfer structure 24 is configured such that the wafer 18 can be loaded into or unloaded out of a boat (which is a substrate retainer) 26.

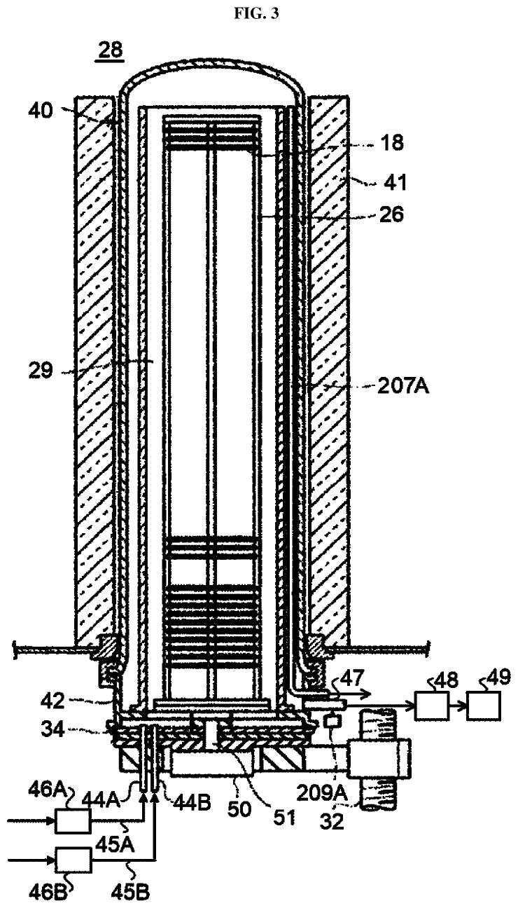

In a rear region of the transfer chamber 23, a standby space 27 where the boat 26 is accommodated in standby is provided, and a process furnace 28 such as a vertical type process furnace is provided above the standby space 27. In addition, a process chamber 29 in which the wafer 18 is processed is provided. The process chamber 29 may also be referred to as a “process vessel” which is an example of a processing structure. A configuration of the process furnace 28 according to the present embodiments will be described with reference to FIG. 3. FIG. 3 is a diagram schematically illustrating a vertical cross-section of the process furnace 28 of the substrate processing apparatus 1 according to the present embodiments.

As shown in FIG. 3, the process furnace 28 includes a process tube 40 serving as a reaction tube. The process chamber 29 in which the wafer 18 is processed is provided within the process tube 40. The process chamber 29 is configured to be capable of accommodating the boat 26. A heater 41 is provided outside the process tube 40. In addition, a temperature sensor 207A is installed within the process tube 40. A manifold 42 is provided below the process tube 40. A reaction vessel is constituted by the process tube 40 and the manifold 42.

A seal cap 34 capable of airtightly closing (sealing) a lower end opening of the manifold 42 is provided below the manifold 42. A process gas nozzle 44A and a purge gas nozzle 44B, which are serving as a gas introduction structure, are connected to the seal cap 34 so as to communicate with an inside of the process chamber 29. A process gas supply pipe 45A is connected to the process gas nozzle 44A. A structure such as a process gas supply source (not shown) is connected to an upstream side of the process gas supply pipe 45A via an MFC (Mass Flow Controller) 46A serving as a gas flow controller. A purge gas supply pipe 45B is connected to the purge gas nozzle 44B. A structure such as a purge gas supply source (not shown) is connected to an upstream side of the purge gas supply pipe 45B via an MFC 46B.

An exhaust pipe 47 through which an inner atmosphere of the process chamber 29 is exhausted is provided at the manifold 42. For example, a pressure sensor 209A, a pressure regulator (which is a pressure adjusting structure) 48 (which is constituted by a component such as an APC (Automatic Pressure Controller)) and a vacuum pump 49 are sequentially installed at a downstream portion of the exhaust pipe 47 in this order from an upstream side to a downstream side of the exhaust pipe 47.

A rotator (which is a rotating structure) 50 configured to rotate the boat 26 is provided at the seal cap 34 in a manner opposite to the process chamber 29. A rotating shaft 51 of the rotator 50 is supports the boat 26 from under by passing through the seal cap 34. The rotator 50 is configured to rotate the wafer 18 by rotating the boat 26.

The seal cap 34 may be elevated or lowered in the vertical direction by a boat elevator 32. The boat elevator 32 is configured to be capable of transferring (loading) the boat 26 into the process chamber 29 and transferring (unloading) the boat 26 out of the process chamber 29 by elevating and lowering the seal cap 34 in the vertical direction.

The boat 26 is configured such that a plurality of wafers (for example, from 50 wafers to 125 wafers) including the wafer 18 are supported on the boat 26 in a horizontal orientation in a multistage manner with their centers aligned with one another. Hereinafter, the plurality of wafers including the wafer 18 may also be simply referred to as “wafers 18”. Further, in the present specification, a notation of a numerical range such as “from 50 wafers to 125 wafers” means that a lower limit and an upper limit are contained in the numerical range. Therefore, for example, a numerical range “from 50 wafers to 125 wafers” means a range equal to or higher than 50 wafers and equal to or less than 125 wafers. The same also applies to other numerical ranges described in the present specification.

Subsequently, an operation of the substrate processing apparatus I will be described.

When the pod 9 is supplied to the loading port 8, the pod loading/unloading port 6 is opened by the front shutter 7. Then, the pod 9 placed on the loading port 8 is transferred (loaded) into the housing 2 through the pod loading/unloading port 6 by the pod transfer structure 15, and is placed on a designated shelf plate among the plurality of shelf plates 13 of the rotatable pod shelf 11. The pod 9 is temporarily stored in the rotatable pod shelf 11. Then, the pod 9 is transferred from the designated shelf plate among the plurality of shelf plates 13 to the pod opener 14 and the placement table 21. Alternatively, the pod 9 may be transferred directly from the loading port 8 to the placement table 21.

When an end surface of the pod 9 placed on the placement table 21 is pressed against an opening edge of the wafer loading/unloading port 19 of the front wall 17 of the sub-housing 16, the attaching/detaching structure 22 detaches the lid of the pod 9 and the wafer entrance of the pod 9 is opened.

When the pod 9 is opened by the pod opener 14, the wafer 18 is then taken out from the pod 9 by the wafer transfer structure 24. Then, by the wafer transfer structure 24, the wafer 18 is transferred (or loaded) into the standby space 27, and loaded (or charged) into the boat 26.

When a predetermined number of wafers including the wafer 18 are charged into the boat 26, a furnace opening of the process furnace 28 closed by a furnace opening shutter 31 is opened by the furnace opening shutter 31. Subsequently, the boat 26 is elevated by the boat elevator 32 such that the boat 26 is loaded (inserted) into the process chamber 29.

After the boat 26 is loaded, the furnace opening is airtightly closed by the seal cap 34. Further, according to the present embodiments, at this timing (that is, after the boat 26 is loaded), a purge step (also referred to as a “pre-purge step”) of replacing the inner atmosphere of the process chamber 29 with an inert gas may be performed. As the inert gas, for example, a nitrogen (N)-containing gas may be used. As the nitrogen-containing gas, for example, a gas such as nitrogen (N₂) gas and ammonia (NH₃) gas may be used. Further, as the nitrogen-containing gas, for example, one or more of the gases exemplified above may be used.

The process chamber 29 is vacuum-exhausted by the vacuum pump 49 such that a pressure (inner pressure) of the process chamber 29 reaches and is maintained at a desired pressure (vacuum degree). Further, the process chamber 29 is heated to a predetermined temperature by the heater 41 such that a desired temperature distribution of the process chamber 29 is obtained.

Further, a process gas whose flow rate is controlled to a predetermined flow rate by the MFC 46A is supplied. The process gas comes into contact with a surface of the wafer 18 while flowing through the process chamber 29. Thereby, a predetermined processing such as a substrate processing described later is performed on the surface of the wafer 18. Further, the process gas after a reaction of the predetermined processing is exhausted from the process chamber 29 by a gas exhaust structure (which is a gas exhauster). In the present specification, the term “process gas” refers to a gas supplied into the process chamber 29. The same also applies to the following description.

After a predetermined process time has elapsed, the inert gas is supplied from an inert gas supply source (that is, the purge gas supply source described above) (not shown). Specifically, the inert gas whose flow rate is controlled to a predetermined flow rate by the MFC 46B is supplied. Thereby, the inner atmosphere of the process chamber 29 is replaced with the inert gas, and the inner pressure of the process chamber 29 is returned to the normal pressure (after-purge step). Then, the boat 26 is lowered by the boat elevator 32 through the seal cap 34. In the present specification, the term “process time” refers to a time duration of continuously performing a process related thereto. The same also applies to the following description.

After the wafer 18 is processed, the wafer 18 and the pod 9 are transferred (unloaded) out of the housing 2 in an order reverse to that of loading the wafer 18 and the pod 9 into the housing 2 described above. Then, another wafer (which is unprocessed) 18 is further loaded into the boat 26, and a batch processing for another wafer 18 is repeatedly performed. For example, the pod 9 accommodating the wafer 18 (which is processed) may be temporarily placed on the rotatable pod shelf 11, then transferred from a designated shelf plate among the plurality of shelf plates 13 to the loading port 8 by the pod transfer structure 15, and then transferred to the outside of the housing 2.

According to the present embodiments, as shown in FIGS. 1 and 2, the substrate processing apparatus 1 includes a control apparatus (which is a control structure) 100, and the control apparatus 100 is configured to control the substrate processing apparatus 1. The control apparatus 100 may be provided (embedded) in the substrate processing apparatus 1, or may be provided outside the substrate processing apparatus 1 in a manner accessible thereto.

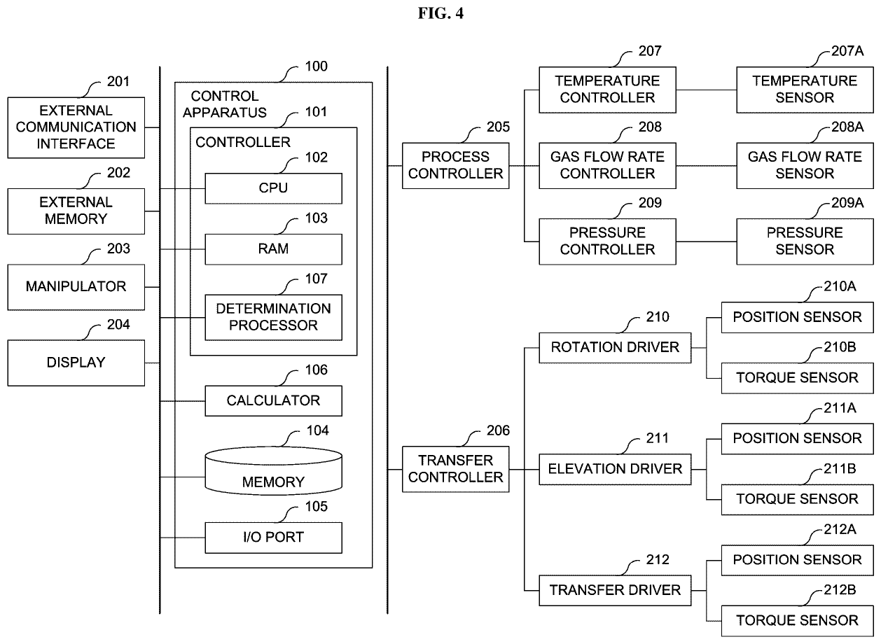

Subsequently, with reference to FIG. 4, a configuration of a control system of the substrate processing apparatus 1 according to the present embodiments will be described. FIG. 4 is a block diagram schematically illustrating an example of a functional configuration of the control apparatus 100 of the substrate processing apparatus 1 according to the present embodiments.

As shown in FIG. 4, the substrate processing apparatus 1 includes the control apparatus (which is a main controller) 100, an external communication interface 201, an external memory 202, a manipulator 203, a display (which is a display structure) 204, a process controller 205 and a transfer controller 206.

For example, the control apparatus 100 includes a controller 101, a memory 104, an I/O port (input/output port) 105 and a calculator (which is a calculating structure) 106. Further, the controller 101 includes a CPU (Central Processing Unit) 102, a RAM (Random Access Memory) 103 and a determination processor 107. In addition, while the calculator 106 is illustrated separately from the controller 101, the calculator 106 may be implemented as a function of the controller 101. In addition, while the determination processor 107 is illustrated as a function of the controller 101, the determination processor 107 may be implemented separately from the controller 101.

The control apparatus 100 is connected to the manipulator 203, and also connected to the process controller 205 and the transfer controller 206 via the I/O port 105. Since the control apparatus 100 is electrically connected to each of the process controller 205 and the transfer controller 206 via the I/O port 105, for example, each piece of data can be transmitted or received and each file can be downloaded or uploaded between the control apparatus 100 and each of the process controller 205 and the transfer controller 206.

The control apparatus 100 is connected to an external host computer (not shown) via the external communication interface 201. Therefore, even when the substrate processing apparatus 1 is installed in a clean room, the host computer can be disposed at a location such as an office outside the clean room. In addition, the external memory 202 (which serves as a mounting structure on which a recording medium such as a USB (Universal Serial Bus) memory is installed or removed) is connected to the control apparatus 100.

For example, the manipulator 203 is configured as a touch panel which is integrated with the display 204 as a single structure or which is connected to the display 204 via a connector such as a video cable. For example, the display 204 is configured as a liquid crystal display panel. Various operation screens for operating the substrate processing apparatus 1 can be displayed on the display 204. For example, the operation screen may include a screen through which a state of a substrate process system controlled by the process controller 205 and a state of a substrate transfer system controlled by the transfer controller 206 can be checked. The display 204 may be provided with various operation buttons serving as an input interface through which an operation instruction can be input via the manipulator 203 to the substrate process system and the substrate transfer system. The manipulator 203 displays information generated in the substrate processing apparatus 1 on the display 204 via the operation screen. For example, the manipulator 203 outputs the information displayed on the display 204 to a device such as the USB memory inserted in the external memory 202. The manipulator 203 accepts (or receives) input data (input instruction) from the operation screen displayed on the display 204 and transmits the input data to the control apparatus 100. Further, the manipulator 203 is configured to receive an instruction (control instruction) to execute an appropriate substrate processing recipe (also referred to as a “process recipe”) among recipes expanded in the RAM 103 or recipes stored in the memory 104, and is further configured to transmit the instruction to the control apparatus 100. For example, the manipulator 203 and the display 204 may be configured as a touch panel. In the present embodiments, the manipulator 203 and the display 204 are provided separately from the control apparatus 100. However, the manipulator 203, the display 204 and the control apparatus 100 may be integrated into a single body.

The process controller 205 includes a temperature controller 207, a gas flow rate controller 208 and a pressure controller 209. Each of the temperature controller 207, the gas flow rate controller 208 and the pressure controller 209 constitutes a sub-controller, and is electrically connected to the process controller 205. Thereby, for example, each piece of data can be transmitted or received and each file can be downloaded or uploaded between the process controller 205 and each sub-controller. In addition, while the process controller 205 and each sub-controller (that is, the temperature controller 207, the gas flow rate controller 208 and the pressure controller 209) are illustrated separately, the process controller 205 and each sub-controller may be integrated into a single body.

A heating structure constituted mainly by the heater 41 and the temperature sensor 207A is connected to the temperature controller 207. The temperature controller 207 is configured to control a process temperature based on measured values detected by the temperature sensor 207A. Specifically, the temperature controller 207 is configured to adjust a temperature (inner temperature) of the process chamber 29 or a temperature of the wafer 18 by controlling a temperature of the heater 41. In the present specification, the term “process temperature” refers to the temperature of the wafer 18 or the inner temperature of the process chamber 29.

The gas flow rate controller 208 is constituted mainly by the MFC 46A and the MFC 46B to which a gas flow rate sensor 208A is connected. The gas flow rate controller 208 is configured to adjust a flow rate of the gas (which is supplied into the process chamber 29) to a desired flow rate based on measured values detected by the gas flow rate sensor 208A.

The gas exhaust structure constituted mainly by the pressure sensor 209A and the pressure regulator 48 is connected to the pressure controller 209. For example, the gas exhaust structure may further include the vacuum pump 49. The pressure controller 209 is configured to control a process pressure based on pressure values detected by the pressure sensor 209A. Specifically, the pressure controller 209 is configured to control a switching operation (on/off operation) of the pressure regulator 48 and a switching operation of the vacuum pump 49 such that the inner pressure of the process chamber 29 reaches and is maintained at a desired pressure at a desired timing. In the present specification, the term “process pressure” refers to the inner pressure of the process chamber 29.

The transfer controller 206 includes a rotation driver 210, an elevation driver 211 and a transfer driver 212. In addition, while the transfer controller 206, the rotation driver 210, the elevation driver 211 and the transfer driver 212 are illustrated separately, the transfer controller 206, the rotation driver 210, the elevation driver 211 and the transfer driver 212 may be integrated into a single body. The rotation driver 210 is configured to control a rotation drive system of the substrate processing apparatus 1. For example, the rotation drive system is constituted by the pod transfer structure 15, the wafer transfer structure 24, a rotating shaft 12 disposed at a center of the rotatable pod shelf 11, the rotator 50 and the rotating shaft 51. The rotation driver 210 is configured to control an operation of the rotation drive system based on measured values of a position sensor 210A and a torque sensor 210B.

The elevation driver 211 is configured to control an elevation drive system of the substrate processing apparatus 1. The elevation driver 211 is configured to control an operation of the elevation drive system based on measured values of a position sensor 211A and a torque sensor 211B. The transfer driver 212 is configured to control a transfer drive system of the substrate processing apparatus 1. The transfer driver 212 is configured to control an operation of the transfer drive system based on measured values of a position sensor 212A and a torque sensor 212B. For example, each of the elevation driver 211 and the transfer driver 212 is configured to control transfer operations of the boat elevator 32, the pod transfer structure 15 and the wafer transfer structure 24.

Further, in the present embodiments, the temperature sensor 207A, the gas flow rate sensor 208A, the pressure sensor 209A, the position sensor 210A, the torque sensor 210B, the position sensor 211A, the torque sensor 211B, the position sensor 212A and the torque sensor 212B may be collectively referred to as “various sensors provided in the substrate processing apparatus 1”, or may be simply referred to as “sensors”.

According to the present embodiments, each of the control apparatus 100, the process controller 205 and the transfer controller 206 may be embodied by a general computer system instead of a dedicated computer system. For example, by installing in the general computer system a program for executing the predetermined processing described above from a predetermined recording medium such as a CD-ROM and a USB memory storing the program, each controller described above may be provided to perform the predetermined processing.

Further, a method of supplying the program described above can be appropriately selected. Instead of or in addition to being supplied through the predetermined recording medium as described above, for example, the program may be provided through a communication interface such as a communication line, a communication network and a communication system.

Further, the control apparatus 100 is configured as a computer including the CPU 102, the RAM 103, the memory 104 and the I/O port 105. In the memory 104, a recipe file such as a recipe in which process conditions and process procedures of the substrate processing are defined, a control program file for executing the recipe file, a parameter file (setting value file) in which parameters for setting the process conditions and the process procedures are defined, an error processing program file, a parameter file for an error processing, various screen files including an input screen to be used to input process parameters and various icon files and the like (which are not shown) are stored (or saved). For example, the control apparatus 100 is electrically connected to a network such as the Internet, a LAN (Local Area Network) and a WAN (Wide Area Network) by using the external communication interface 201, and is configured to be capable of communicating with external apparatuses via the network.

As the memory 104, for example, a component such as a hard disk drive (HDD), a solid state drive (SSD) and a flash memory may be used. Further, in the memory 104, a calculation processing program for executing an energy consumption amount calculation process according to the present embodiments is stored.

For example, the calculation processing program is installed in advance in the substrate processing apparatus 1. The calculation processing program may be implemented by appropriately installing the calculation processing program (which may be recorded on a non-volatile recording medium or distributed via the network) in the substrate processing apparatus 1. As the non-volatile recording medium, for example, a component such as a CD-ROM, a magneto-optical disk, a HDD, a DVD-ROM, a flash memory, a memory card and a USB may be used.

That is, the calculation processing program is a program that causes the substrate processing apparatus 1, by the computer, to perform: (a) processing the substrate based on at least one setting item in which the process conditions for the substrate are defined; (b) performing a setting operation for the process conditions of the at least one setting item; (c) calculating an energy amount (that is, an amount of energy) consumed under the process conditions which are set in (b); and (d) processing the substrate based on the process conditions which are set in (b).

The CPU 102 of the substrate processing apparatus 1 according to the present embodiments functions as the controller 101 (which includes the determination processor 107), the calculator 106 by writing the calculation processing program stored in the memory 104 to the RAM 103 and executing the calculation processing program. When the determination processor 107 is provided separately from the controller 101, the CPU 102 may also function as the determination processor 107.

The substrate processing apparatus 1 according to present embodiments includes the process chamber 29, the controller 101 and the manipulator 203.

The process chamber 29 is configured to process the substrate (that is, the wafer 18) based on the at least one setting item in which the process conditions for the substrate are defined. That is, the substrate is processed in the process chamber 29.

The manipulator 203 is configured to perform the setting operation for the process conditions of the at least one setting item. That is, the manipulator 203 performs an editing operation on the at least one setting item (in which the process conditions for the substrate are defined) via the operation screen.

For example, according to the present embodiments, by using a recipe editing screen displayed by the display 204 as the operation screen, the manipulator 203 performs an editing operation on the setting item (or the setting items).

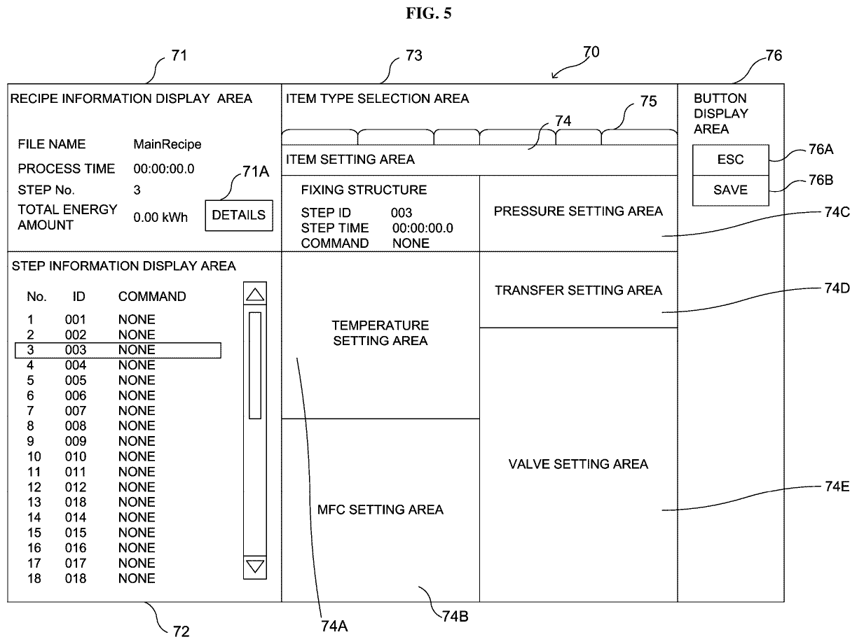

An example of setting the process conditions of the setting item (or the setting items) according to the preset embodiments will be specifically described with reference to FIG. 5. FIG. 5 is a diagram schematically illustrating an example of a configuration of the recipe editing screen according to the present embodiments. For example, the recipe editing screen 70 shown in FIG. 5 includes a recipe information display area 71, a step information display area 72, an item type selection area 73, an item setting area 74 and a button display area 76.

In the recipe information display area 71, for example, a recipe name (file name), the process time, a step number (“STEP No.” shown in FIG. 5) of a currently selected step and a total energy amount may be displayed. In the present specification, the term “total energy amount” refers to a total amount of the energy calculated by the calculator 106. In addition, in the recipe information display area 71 according to the preset embodiments, a details button (“DETAILS” shown in FIG. 5) 71A may also be displayed as an icon for instructing a calculation of the energy amount. When the details button 71A is pressed (for example, by an operation such as a touch operation and a cursor operation), details of the energy amount calculated by the calculator 106 are displayed. The detailed display of the energy amount will be described later.

In the step information display area 72, for example, a list of step information registered in the recipe is displayed. For example, the step information may include: a step number of each step; a step process time for each step; a step name (“ID” shown in FIG. 5) of each step; and a presence or absence of an execution command. In the example shown in FIG. 5, a state in which a step corresponding to “No. 3” is selected is displayed. Further, the step information display area 72 is an area for displaying each step (procedure) for processing the wafer 18, for example, by the process gas supplied to the surface of the wafer 18, and also is an area for selecting the step to be edited. In addition, the steps may be separated by a period for calculating the energy amount. For example, as such a period, at least one selected from the group of a temperature elevation period, a temperature lowering period and a stable period in the process chamber 29 may be used. In addition, for example, as such a period, a period corresponding to a demarcation of an individual processing of the substrate may be used. In addition, for example, as such a period, a period during which a transfer structure for transferring the substrate is in operation may be used. In the example shown in FIG. 5, the periods mentioned above correspond to the steps, and by selecting a step, at least one of the periods can be selected.

In the item type selection area 73, items to be displayed in the item setting area 74 are displayed in a selectable manner. In the present embodiments, the term “items” are examples of the setting items. For example, the items which are selectable (hereinafter, also referred to as “selectable items”) may include a temperature, the MFCs, a pressure, a transfer control (transfer structure) and the valves. In the item setting area 74, the selectable items are displayed such that they can be set by the manipulator 203.

In the example shown in FIG. 5, the item setting area 74 includes a temperature setting area 74A, an MFC setting area 74B, a pressure setting area 74C, a transfer setting area 74D and a valve setting area 74E. The temperature setting area 74A is an area for setting information related to the process temperature controlled by the temperature controller 207. For example, information which can be set (hereinafter, also referred to as “settable information”) by using the temperature setting area 74A may include a name, a temperature setting value and a ramp rate value. The MFC setting area 74B is an area for setting information related to the flow rate of the gas in the process furnace 28 controlled by the MFC 46A and the MFC 46B (which serve as the gas flow rate controller 208). For example, settable information by using the MFC setting area 74B may include a name and a gas flow rate setting value. The pressure setting area 74C is an area for setting information related to the process pressure controlled by the pressure controller 209. For example, settable information by using the pressure setting area 74C may include a name of a mode for controlling the pressure, a command for controlling the pressure and a pressure setting value. The transfer setting area 74D is an area for setting information related to the transfer control of the rotation driver 210, the elevation driver 211 and the transfer driver 212. For example, settable information by using the transfer setting area 74D may include commands for controlling the transfer structure. The valve setting area 74E is an area for setting information related to the valves provided in the process furnace 28. For example, settable information by using the valve setting area 74E may include a name and a valve state (on/off state). The item type selection area 73 may include tabs 75 corresponding to each of the items mentioned above, and detailed information related to each item can be set by selecting each of the tabs 75.

In addition, the selectable items (that is, the items which are selectable) are not limited to those exemplified in FIG. 5, and may be any items that define conditions related to the substrate processing in the substrate processing apparatus 1.

In the button display area 76, a plurality of buttons such as an Esc button (“ESC” shown in FIG. 5) 76A and a Save button (“SAVE” shown in FIG. 5) 76B are displayed.

When the Esc button 76A is pressed, an operation of closing the recipe editing screen 70 is performed. When the Save button 76B is pressed, an operation of saving (storing) contents edited on the recipe editing screen 70 is performed. The contents of the recipe editing screen 70 may be stored in the memory 104 or in the external memory 202. By storing the recipe (which is edited) in a manner described above, it is possible to process the substrate based on the recipe which is stored.

In the example shown in FIG. 5, when the details button 71A on the recipe editing screen 70 is pressed, an energy consumption amount (that is, the energy amount consumed) under the process conditions (which are set) is calculated. By calculating the energy consumption amount at the timing when the details button 71A is pressed, it is possible to reduce a burden on the substrate processing apparatus 1. The controller 101 is configured to be capable of controlling a calculation of the energy consumption amount under the process conditions (which are set). According to the present embodiments, by controlling the calculator 106, the controller 101 is configured to be capable of controlling the calculation of the energy consumption amount under the process conditions (which are set). For example, when the burden on the substrate processing apparatus 1 is low, the energy amount may be calculated when the recipe editing screen 70 is launched (or displayed), and a calculation result may be displayed in the total energy amount on the recipe editing screen 70.

The calculator 106 is configured to calculate the energy amount. The energy amount calculated by the calculator 106 is calculated from the at least one setting item. Specifically, the calculator 106 calculates the energy consumption amount in accordance with the process conditions of the at least one setting item (which is set on the recipe editing screen 70). That is, an energy consumption amount calculation process is performed. The energy consumption amount calculation process refers to a process of calculating the energy consumption amount when the processing is performed under the process conditions of the setting items (which are set). The term “energy consumption amount” described above may include an energy amount (also referred to as a “first energy amount”) calculated before the processing of the substrate is performed and an energy amount (also referred to as a “second energy amount”) calculated during or after the processing of the substrate is performed. The first energy amount is an energy amount calculated based on the process conditions of the setting items (which are set by the manipulator 203). In other words, the first energy amount is an energy amount estimated to be consumed (also referred to as an “estimated energy amount”). On the other hand, the second energy amount is an energy amount calculated using measured values (which are obtained from various sensors provided in the substrate processing apparatus 1) as data reported during the substrate processing by actually processing the substrate based on the process conditions of the setting items (which are set by the manipulator 203) as the recipe. In other words, the second energy amount is an energy amount actually consumed (also referred to as an “actual energy amount”). However, the estimated energy amount may be derived during or after actually processing the substrate based on the process conditions of the setting items (which are set by the manipulator 203) as the recipe.

By using a predetermined calculation method such as a calculation formula or calculation table stored in the memory 104, the calculator 106 of the present embodiments calculates the energy consumption amount. For example, when the calculator 106 of the present embodiments uses the calculation method and the calculation formula defined in the SEMI Standard (in the present embodiment, for example, the SEMI Standard S23) and calculates the energy consumption amount using parameters defined for each item compliant with the standard (that is, each type of the energy to be calculated), the parameters may be adjusted. For example, the parameters may be adjusted depending on a process result of the substrate.

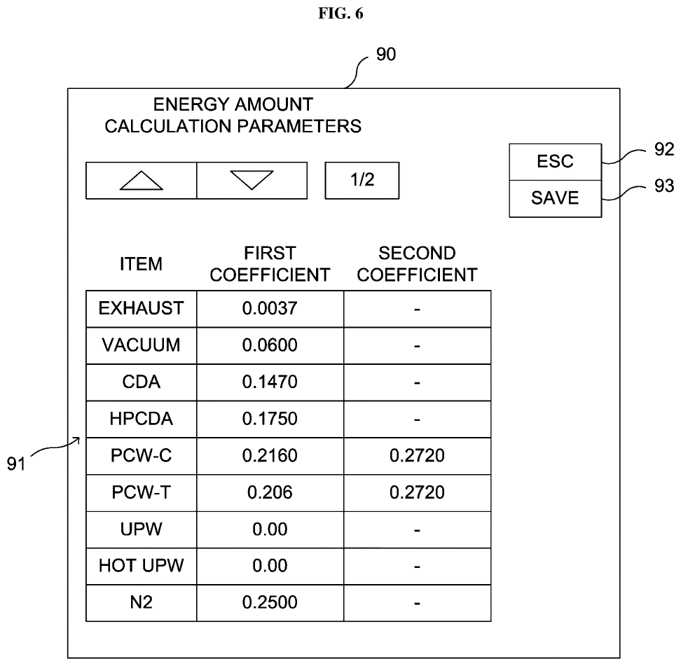

FIG. 6 is a diagram schematically illustrating an example of a configuration of a parameter setting screen 90 according to the present embodiments. The parameter setting screen 90 shown in FIG. 6 may include an item-by-item parameter setting area 91, an Esc button (“ESC” shown in FIG. 6) 92, and a Save button (“SAVE” shown in FIG. 6) 93. In the item-by-item parameter setting area 91, a first coefficient and a second coefficient are displayed as parameters used to calculate the energy consumption amount for each item defined in the SEMI Standard. When the Esc button 92 is pressed, an operation of closing the parameter setting screen 90 is performed. When the Save button 93 is pressed, an operation of saving (storing) the parameters (that is, the first coefficient and the second coefficient) set on the parameter setting screen 90 is performed. The parameters (which are set by using the parameter setting screen 90) may be stored in the memory 104 or the external memory 202. Since the parameters are capable of being adjusted, it is possible to change calculation conditions for the energy amount depending on the configuration, a machine difference and aging of the substrate processing apparatus 1. Further, when the number of the items displayed on the item-by-item parameter setting area 91 is greater than the number of the items capable of being displayed in the item-by-item parameter setting area 91, a button or scroll bar for switching items may be further provided.

In addition, the calculator 106 of the present embodiments calculates the energy amount for a predetermined period. Specifically, the calculator 106 calculates the energy consumption amount for a period corresponding to the step selected in the step information display area 72 of the recipe editing screen 70 described above. For example, by determining the period for calculating the energy consumption amount, it is possible to easily compare the energy consumption amount (which is calculated in a manner described above) with that consumed under similar process conditions of other similar recipes.

For example, as described above, by calculating an energy consumption in at least one selected from the group of the temperature elevation period, the temperature lowering period and the stable period or in the period corresponding to the demarcation of the individual processing of the substrate, it is possible to clarify how much energy is consumed in each period. Thereby, for example, it is possible to consider reducing the energy consumption amount in a period where a large amount of the energy is consumed. In addition, for example, by calculating the energy consumption in a period in which the transfer structure configured to transfer the substrates is in operation, as described above, it is possible to calculate the energy consumption amount not only in the substrate process system, but also in the transfer system. By calculating the energy consumption in the substrate process system and the transfer system as described above, it is also possible to calculate the energy consumption amount in an entirety of the substrate processing apparatus 1.

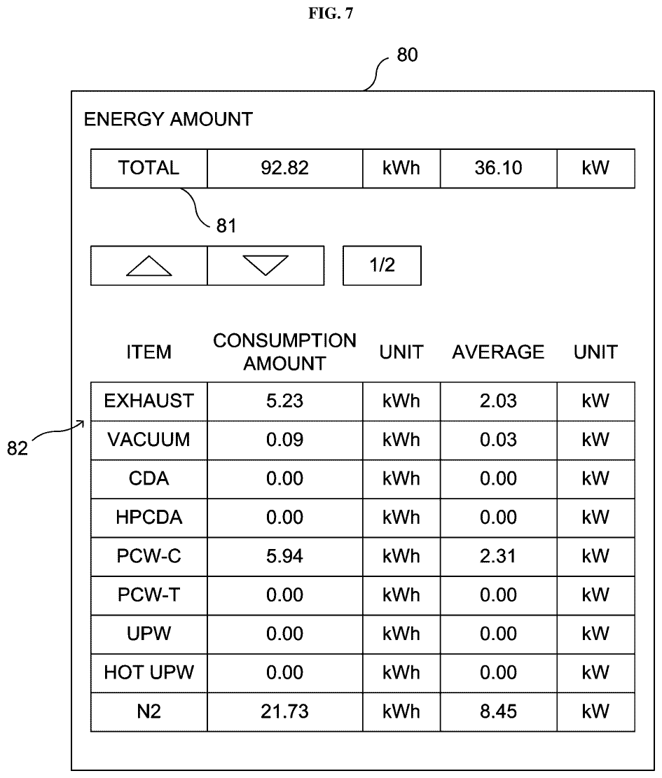

The energy consumption amount calculated by the calculator 106 is displayed by the display 204. FIG. 7 is a diagram schematically illustrating an example of a configuration of an energy consumption amount display screen 80 according to the present embodiments. For example, the energy consumption amount display screen 80 and the recipe editing screen 70 may be displayed side by side, or one of the energy consumption amount display screen 80 and the recipe editing screen 70 may be displayed in a switchable state. In addition, the energy consumption amount display screen 80 may be always displayed in front of the recipe editing screen 70.

The energy consumption amount display screen 80 shown in FIG. 7 includes a total consumption amount display area 81 and an item-by-item consumption amount display area 82. In the total consumption amount display area 81, a sum of the energy consumption amount (consumption amount) for each item displayed in the item-by-item consumption amount display area 82 is displayed as “TOTAL”. In addition, the calculator 106 of the present embodiments calculates the energy consumption amount based on an electric power value used for processing the substrate, and displays the energy consumption amount based on the electric power value on the energy consumption amount display screen 80. In FIG. 7, an example in which “kWh” is used as the unit of the electric power value to be calculated, and “kW” is used as an average thereof. By displaying the energy consumption amount as the electric power value in a manner described above, it is possible to provide the energy consumption amount as unified information.

In addition, in the item-by-item consumption amount display area 82, the energy consumption amount calculated by the calculator 106 for each item defined in the SEMI Standard is displayed. In a manner described above, the energy amount (energy consumption amount) calculated and displayed in the present embodiments corresponds to a type that complies with the SEMI Standard. As a result, it is possible to provide the energy consumption amount that complies with the standard. In such a case, for example, it is possible to ensure the reliability of the energy consumption amount calculated as described above. Further, in such a case, it may be suitable that the energy amount consumed for one or more items defined in the SEMI Standard is calculated and displayed.

In addition, a carbon dioxide (CO₂) emission amount converted into an amount of the CO₂ emitted may be calculated. Then, in the energy consumption amount display screen 80, instead of or in addition to the electric power value, the CO₂ emission amount may be displayed as the energy consumption amount. In such a case, the calculator 106 converts the electric power value into the CO₂ emission amount using a predetermined CO₂ emission coefficient. For example, In addition, a value of the CO₂ emission coefficient may vary depending on a region and the like. Therefore, for example, the CO₂ emission coefficient corresponding to the region (in which the substrate processing apparatus 1 is installed) and the like may be stored in advance, or the CO₂ emission coefficient may be selected from a plurality of CO₂ emission coefficients as appropriate. By calculating the CO₂ emission amount in a manner described above, the amount of the CO₂ emitted by the substrate processing apparatus 1 can be clarified.

Further, in the present embodiments, a threshold value for the energy amount (energy consumption amount) calculated by the calculator 106 is provided (or set) in advance, and the determination processor 107 is configured to compare the energy consumption amount calculated by the calculator 106 with the threshold. The threshold used in the present embodiments defines a target value for the energy consumption amount. For example, as the threshold, a value obtained from an experimental result (or an energy consumption amount calculated from a recipe result that has been normally completed in the past) may be used. For example, the threshold may be defined in advance in the memory 104. The threshold used in the present embodiments may be one or both of an upper limit value and a lower limit value. Further, the threshold may be set for a total consumption amount (total energy consumption amount), or may be set for a consumption amount (energy consumption amount) for each item.

By setting the threshold value in a manner described above and by performing a determination process using the threshold value by the determination processor 107, it is possible to easily determine whether or not a target is met.

The controller 101 notifies the display 204 of a determination result by the determination processor 107. Specifically, the controller 101 notifies the display 204 of whether or not the energy consumption amount calculated by the calculator 106 exceeds the threshold value as the determination result by determination processor 107. In such a case, the display 204 receives a notification from the controller 101 and issues a warning when the determination result indicates that the energy consumption amount exceeds the threshold value. As an example of the warning, a message indicating the warning may be displayed on one or both of the energy consumption amount display screen 80 and the recipe editing screen 70. By issuing the warning in a manner described above, it is possible to avoid creating a recipe that wastes an unnecessary amount of the energy.

Further, when the determination result is that the energy consumption amount exceeds the threshold value, the display 204 may switch a display of the energy consumption amount into a state different display from normal. For example, among the items displayed in the item-by-item consumption amount display area 82, the displayed item corresponding to the determination result (that is, the energy consumption amount exceeds the threshold value) may be switched into a state different from those of the other items. For example, the “different state” may include a different character decoration such as a color, a character font and an underlining and a character size. By visually differentiating the item (which corresponds to the determination result that the energy consumption amount exceeds the threshold value) from the other items in a manner described above, the differences can be clarified.

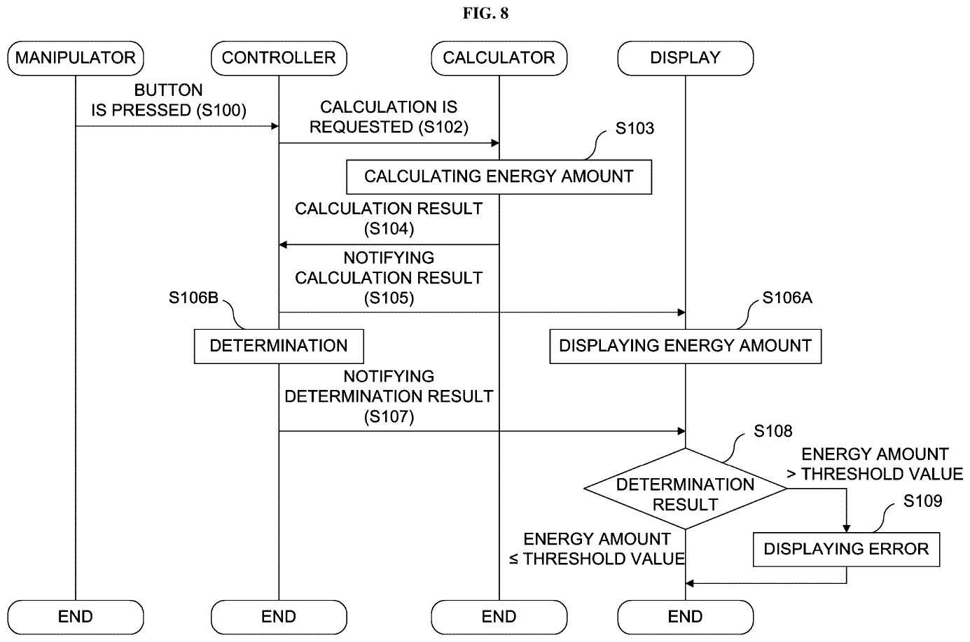

Subsequently, the operation of the substrate processing apparatus 1 according to the present embodiments will be described with reference to FIG. 8. FIG. 8 is a flow chart schematically illustrating an example of a sequence of the energy consumption amount calculation process according to the present embodiments. As an example, in the present embodiments, the energy consumption amount calculation process shown in FIG. 8 is performed while the energy consumption amount display screen 80 is displayed by the display 204.

In a step S100, the manipulator 203 notifies the controller 101 that the details button 71A displayed on the energy consumption amount display screen 80 of the display 204 has been pressed.

In a step S102, in response to the notification, the controller 101 requests the calculator 106 to calculate the energy consumption amount.

In a step S103, the calculator 106 calculates the energy consumption amount based on the setting items set on the recipe editing screen 70 as described above.

In a step S104, the calculator 106 outputs the calculation result (that is, the energy consumption amount calculated by the calculator 106) to the controller 101.

In a step S105, the controller 101 notifies the display 204 of the calculation result by the calculator 106. As a result, in step a S106A, the display 204 displays the amount of the energy calculated by the calculator 106 (that is, the energy consumption amount) on the energy consumption amount display screen 80 described above.

Further, in a step S106B, the determination processor 107 of the controller 101 compares the calculation result with the threshold value as described above. In a step S107, the controller 101 notifies the display 204 of the determination result by the determination processor 107 as described above.

In a step S108, the display 204 determines whether the determination result is that the energy consumption amount exceeds the threshold value. When the energy amount (that is, the energy consumption amount) calculated by the calculator 106 exceeds the threshold value, in a step 109, the display 204 displays an error as the warning described above. When a processing of the step S109 is terminated, the energy consumption amount calculation process shown in FIG. 8 is terminated. On the other hand, when the energy amount (that is, the energy consumption amount) calculated by the calculator 106 does not exceed the threshold value, the energy consumption amount calculation process shown in FIG. 8 is also terminated.

In a manner described above, the substrate processing apparatus 1 of the present embodiments is configured to be capable of being controlled by the controller 101 of the control apparatus 100 and the manipulator 203 to calculate the energy amount consumed under the process conditions of the setting items.

Therefore, the energy amount suitable for processing the substrate (that is, the energy consumption amount) can be calculated before the processing is performed on the substrate, and the energy amount suitable for processing the substrate can be recognized. In addition, it is possible to modify the process conditions of the setting items based on the energy amount calculated in a manner described above before processing the substrate. Thereby, it is possible to reduce the energy consumption amount for processing the substrate.

Further, when the details button 71A on the recipe editing screen 70 is pressed during the substrate processing, the calculator 106 may calculate the energy amount (energy consumption amount) based on output values from each sensor of the substrate processing apparatus 1 obtained during the substrate processing. In such a case, the display 204 is capable of displaying the energy consumption amount during the substrate processing. Thereby, for example, it is possible to modify the recipe in advance before performing a subsequent recipe.

Furthermore, the calculator 106 may calculate the estimated energy amount and the actual energy amount as described above. In such a case, the display 204 can display a comparison result between the estimated energy amount and the actual energy amount. Thereby, it is possible to clearly indicate a difference between the estimated energy amount and the actual energy amount. Further, with respect to the actual energy amount, the amount of energy consumed in the period (which is set as described above) may also be calculated. Thereby, it is possible to easily compare the estimated energy amount and the actual energy amount.

In addition to a form of the energy consumption amount display screen 80 shown in FIG. 7, or instead of the form of the energy consumption amount display screen 80, the display 204 may display the energy amount for each period of the substrate processing in a chronological order. That is, the display 204 may display the energy consumption amount for each period in which the calculator 106 calculates the energy consumption amount in a chronological order. As the form of displaying the energy consumption amount in a chronological order, for example, a table format or a chart format may be used. For example, when the table format is used, the energy consumption amount may be displayed with a vertical axis indicating the period (step) and a horizontal axis indicating the energy amount (energy consumption amount). In addition, when the estimated energy amount and the actual energy amount are displayed as described above, the difference therebetween may also be displayed. In addition, for example, when the chart format is used, the estimated energy amount at the time of setting the recipe and the actual energy amount at the time of performing the processing according to the recipe (which is set) may be plotted with a horizontal axis indicating the period (step) and a vertical axis indicating the energy amount (energy consumption amount). In such a case, the threshold value may also be displayed. By displaying in a chronological order in a manner described above, it is possible to visually clarify the difference.

For example, the substrate processing apparatus 1 according to the embodiments mentioned above is described above as an example. However, the technique of the present disclosure may also be applied to a program that causes a computer to perform the functions of the substrate processing apparatus 1. Further, the technique of the present disclosure may also be applied to a non-transitory computer-readable recording medium storing the program that causes the computer to perform the functions of the substrate processing apparatus 1.

In addition, the configuration of the substrate processing apparatus 1 described in the embodiments mentioned above is merely an example, and may be changed in accordance with circumstances without departing from the scope of the technique of the present disclosure.

In addition, the process flow of the program described in the embodiments mentioned above is merely an example, and may be changed. For example, an unnecessary step may be deleted, a new step may be added, or the process procedures may be changed without departing from the scope of the technique of the present disclosure.

For example, the embodiments mentioned above are described by way of an example in which the processing according to the embodiments is implemented by a software configuration that uses the computer to execute the program. However, the technique of the present disclosure is not limited thereto. For example, the technique of the present disclosure may also be applied to a hardware configuration capable of performing the processing, or may also be applied to a combination of hardware and software configurations capable of performing the processing.

For example, the embodiments mentioned above are described by way of an example in which a batch type substrate processing apparatus capable of simultaneously processing a plurality of substrates is used to form the film. However, the technique of the present disclosure is not limited thereto. For example, the technique of the present disclosure may also be preferably applied when a single wafer type substrate processing apparatus capable of processing one or several substrates at a time is used to form the film. For example, the embodiments mentioned above are described by way of an example in which a substrate processing apparatus including a hot wall type process furnace is used to form the film. However, the technique of the present disclosure is not limited thereto. For example, the technique of the present disclosure may also be preferably applied when a substrate processing apparatus including a cold wall type process furnace is used to form the film.

The process procedure and the process conditions of each process using the substrate processing apparatuses exemplified above may be substantially the same as those of the embodiments mentioned above. Even in such a case, it is possible to obtain substantially the same effects as in the embodiments mentioned above.

According to some embodiments of the present disclosure, it is possible to estimate the energy amount suitable for processing the substrate before the substrate is performed.

What is claimed is:

1. A substrate processing apparatus comprising:
a processing structure configured to process a substrate based on at least one setting item in which process conditions for the substrate are defined;
a manipulator configured to perform a setting operation for the process conditions of the at least one setting item; and
a controller configured to be capable of controlling a calculation of an energy amount consumed under the process conditions which are set by the manipulator.

2. The substrate processing apparatus of claim 1, further comprising:
a calculator configured to perform the calculation of the energy amount,
wherein the energy amount calculated by the calculator is being configured to be calculated from the at least one setting item.

3. The substrate processing apparatus of claim 2, wherein the calculator is further configured to calculate the energy amount for a predetermined period.

4. The substrate processing apparatus of claim 3, wherein the predetermined period is configured to comprise at least one selected from the group of: a temperature elevation period, a temperature lowering period, and a stable period in the processing structure.

5. The substrate processing apparatus of claim 3, wherein the predetermined period is configured to comprise a period corresponding to a demarcation of an individual processing of the substrate.

6. The substrate processing apparatus of claim 3, further comprising:
a transfer structure configured to transfer the substrate,
wherein the predetermined period is configured to comprise a period during which the transfer structure is in operation.

7. The substrate processing apparatus of claim 3, wherein the calculator is further configured to calculate the energy amount for each predetermined period of processing the substrate from a process result of the substrate.

8. The substrate processing apparatus of claim 3, further comprising:
a display configured to display the energy amount,
wherein the display is further configured to display the energy amount for each predetermined period of processing the substrate in a chronological order.

9. The substrate processing apparatus of claim 1, wherein:
the controller comprises a determination processor configured to compare the energy amount and a threshold value;
the threshold value is set in advance for the energy amount; and
the controller is further configured be capable of controlling to notify a determination result determined by the determination processor.

10. The substrate processing apparatus of claim 9, further comprising:
a display configured to display the energy amount,
wherein the display is further configured to receive a notification from the controller and to issue a warning when the determination result indicates that the energy amount exceeds the threshold value.

11. The substrate processing apparatus of claim 9, further comprising:
a display configured to display the energy amount,
wherein the display is further configured to receive a notification from the controller and to switch a displayed item into a state different from those of other items when the determination result indicates that the energy amount exceeds the threshold value.

12. The substrate processing apparatus of claim 1, wherein the energy amount is configured to correspond to an electric power value consumed under the process conditions.

13. The substrate processing apparatus of claim 1, wherein the energy amount is obtained by converting an electric power value consumed under the process conditions into a CO₂ emission amount.

14. The substrate processing apparatus of claim 1, further comprising:
a display configured to display the energy amount,
wherein the energy amount comprises an estimated energy amount calculated from the process conditions and an actual energy amount calculated from data reported during processing the substrate, and
wherein the display is further configured to display a comparison result between the estimated energy amount and the actual energy amount.

15. The substrate processing apparatus of claim 1, wherein the energy amount is configured to correspond to a type compliant with the SEMI Standard.

16. The substrate processing apparatus of claim 15, wherein the energy amount is calculated using parameters defined for each type, and the parameters are configured to be capable of being adjusted depending on a process result of the substrate.

17. The substrate processing apparatus of claim 1, further comprising:
a display configured to display the energy amount,
wherein the display is further configured to display an icon instructing the calculation of the energy amount, and
wherein the manipulator is further configured to request the controller to calculate the energy amount when the icon is selected.

18. The substrate processing apparatus of claim 1, further comprising:
a display configured to display the energy amount,
wherein the display is further configured to display the energy amount during processing the substrate.

19. A method of manufacturing a semiconductor device, comprising:
(a) processing a substrate based on at least one setting item in which process conditions for the substrate are defined;
(b) performing a setting operation for the process conditions of the at least one setting item; and
(c) controlling a calculation of an energy amount consumed under the process conditions which are set in (b).

20. A non-transitory computer-readable recording medium storing a program that causes a substrate processing apparatus, by a computer, to perform:
(a) processing a substrate based on at least one setting item in which process conditions for the substrate are defined;
(b) performing a setting operation for the process conditions of the at least one setting item; and
(c) controlling a calculation of an energy amount consumed under the process conditions which are set in (b).
